(19) United States
(12) Patent Application Publication
(10) Pub. No.: US 2025/0087629 A1
(43) Pub. Date: Mar. 13, 2025

(54) Dicing Street Design for Hybrid Bonding

(71) Applicant: International Business Machines Corporation, Armonk, NY (US)

(72) Inventors: Roy R. Yu, Poughkeepsie, NY (US); Katsuyuki Sakuma, Fishkill, NY (US); Ravi K. Bonam, Albany, NY (US); Nicholas Alexander Polomoff, Hopewell Junction, NY (US); Martin Desrochers, Cowansville (CA); Aakrati Jain, Albany, NY (US); Sathyanarayanan Raghavan, Ballston Lake, NY (US)

(21) Appl. No.: 18/367,807

(22) Filed: Sep. 13, 2023

(51) Int. Cl. H01L 23/00; H01L 21/78; H01L 23/544

(52) U.S. Cl. CPC H01L 24/94; H01L 21/78; H01L 23/544; H01L 24/80; H01L 2224/80895; H01L 2224/80896; H01L 2224/94

(57) ABSTRACT

A structure comprising: a metal free zone within at least one level of the structure; and a fill pattern that is not staggered along a first direction and that is not staggered along a second direction.

### BACKGROUND

The exemplary embodiments described herein relate generally to semiconductor device design and integrated circuit design, and more specifically, to a dicing street design for hybrid bonding.

### SUMMARY

In one aspect, a structure includes: a metal free zone within at least one level of the structure; and a fill pattern that is not staggered along a first direction and that is not staggered along a second direction.

In another aspect, a method includes: forming a metal free zone within at least one level of a structure; and forming a fill pattern that is not staggered along a first direction and that is not staggered along a second direction.

In another aspect, a method includes: forming a metal free zone for at least one level of a device; forming a first wafer; forming a second wafer; bonding the first wafer and the second wafer using a surface to form a structure that comprises the metal free zone; thinning the structure; flipping the structure; and performing stealth dicing of the structure along the metal free zone.

In another aspect, a method includes: forming a dicing street within a structure; depositing fragile material within an area of the dicing street, wherein the fragile material is more fragile than dielectric material formed within other layers of the structure; and exposing the fragile material to an ultraviolet laser to form airgaps within the dicing street

### BRIEF DESCRIPTION OF THE DRAWINGS

The foregoing and other aspects of exemplary embodiments are made more evident in the following Detailed Description, when read in conjunction with the attached Drawing Figures, wherein:

FIG. 1A shows a top panel and a bottom panel, where the top panel of FIG. 1A shows a top view of an intersection of a dicing street x (horizontal) and a dicing street y (vertical), which intersection separates the wafer into Die-1, Die-2, Die-3, and Die-4, and where the bottom panel of FIG. 1A shows a separated die (either from Die-1, Die-2, Die-3, or Die-4) bonded to another bottom die with a solder joint;

FIG. 1B shows a top panel and a bottom panel, where the top panel of FIG. 1B shows a top view of a dicing street x (horizontal) and a dicing street y (vertical), where the intersection of the horizontal dicing street and the vertical dicing street separates the wafer into Die-1, Die-2, Die-3, and Die-4, and where the bottom panel of FIG. 1B shows a separated die (either from Die-1, Die-2, Die-3, or Die-4) hybrid bonded to another bottom die, where the burr impacts a hybrid bond because a dicing street design is not used;

FIG. 1C shows a top panel and a bottom panel, where the top panel of FIG. 1C shows a top view of dicing streets x (horizontal) and y (vertical), where the intersection of the horizontal dicing street and the vertical dicing street separates the wafer into Die-1, Die-2, Die-3, and Die-4, and where the bottom panel of FIG. 1C shows a separated die (either from Die-1, Die-2, Die-3, or Die-4) hybrid bonding without burr impact with use of a dicing street design;

FIG. 2A shows a top-down view of Die-1, Die-2, Die-3, and Die-4 in a dicing intersection between a vertical dicing street and a horizontal dicing street, and a cross-sectional view of the horizontal dicing street, where a typical dicing street design used, and where in the y-direction, the metal fill is staggered;

FIG. 2B shows a top-down view of Die-1, Die-2, Die-3, and Die-4 in a dicing intersection between a vertical dicing street and a horizontal dicing street, and a cross-sectional view of the horizontal dicing street, where a dicing street design described herein is used, and where the metal fills in both the x direction and the y direction are not staggered;

FIG. 3A shows a top-down view of Die-1, Die-2, Die-3, and Die-4, at a dicing intersection of a horizontal dicing street and a vertical dicing street, together with a cross-sectional view of one die of the four dies solder joined to a bottom die;

FIG. 3B shows a top-down view of Die-1, Die-2, Die-3, and Die-4, at a dicing intersection of a horizontal dicing street and a vertical dicing street, together with a cross-sectional view of one die of the four dies hybrid bonded to a bottom die where the edge burr impacts the bonding quality;

FIG. 3C shows a hybrid bonding without burr impact with use of a dicing street design;

FIG. 4A is a top-down view of a dicing street having a Y-direction (e.g. vertical direction) staggered metal fill pattern;

FIG. 4B is a top-down view of a dicing street having a non-staggering fill pattern in both X and Y directions;

FIG. 5A is a view of a dicing street fill pattern with a staggering fill pattern in the vertical direction after the filled is diced;

FIG. 5B is a view of a dicing street fill pattern with a non-staggering fill pattern in both the X and Y directions;

FIG. 6A shows a top view of a dicing street design without a straight path through the metal fills in the horizontal direction, but with several straight paths through the metal fills in the vertical direction;

FIG. 6B shows a view of a die with a dicing street 20 um wide, free of metal fills;

FIG. 7A shows sides of dies separated at picking;

FIG. 7B is an edge on SEM that shows a burr of size 1.3 μm due to laser cutting;

FIG. 8A, FIG. 8B, FIG. 8C, FIG. 8D, and FIG. 8E (collectively FIG. 8) show an example hybrid bonding process flow;

FIG. 9 is a logic flow diagram to implement a method, based on the examples described herein;

FIG. 10 is a logic flow diagram to implement a method, based on the examples described herein;

FIG. 11 shows a top view of a die and a side view of the die, and a cutting location and dicing street of the die;

FIG. 12 shows a top view of a die and a side view of the die, and a cutting location and a dicing street of the die, where an area around the metal is filled with a fragile material;

FIG. 13 shows a top view of a die and a side view of the die, a cutting location and a dicing street of the die, and an area of fragile material;

FIG. 14 shows a top view of a die and a side view of the die, a cutting location and a dicing street of the die, and an area of fragile material;

FIG. 15 shows a first operation of a process flow, based on the examples described herein;

FIG. 16 shows a second operation of a process flow, based on the examples described herein;

FIG. 17 shows a third operation of a process flow, based on the examples described herein;

FIG. 18 shows a fourth operation of a process flow, based on the examples described herein;

FIG. 19 shows a fifth operation of a process flow, based on the examples described herein; and

FIG. 20 is a logic flow diagram to implement a method, based on the examples described herein.

### DETAILED DESCRIPTION

The term “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

Hybrid bonding is an emerging device interconnection technology and a new direction in 3DI stacking allowing significant IO pitch reduction (e.g. 1 μm) compared to solder micropumps (e.g. 50 μm). The bonding may be die-to-die (D2D), or die-to-wafer (D2 W). Hybrid bonding for die-on-die and die-on-wafer has the advantages of having a known good die and variable die sizes from different die sources. An ultra-clean surface (nm), and “burr-free” edges, are required. Dicing quality can affect hybrid bonding by leaving dicing debris on the surface. Another impact to the bonding quality is dicing “burrs” along the edge, especially where metal fills are used in low-K dielectric layers. A metal filled dicing street generates “edge burrs”, which can have significant impact on hybrid bonding quality and joining yield. This is because hybrid bonding takes place at the monolayer molecular level. Dicing edge burrs from metal fills would be easily in excess of 0.5 um. Therefore, elimination of the edge burrs from metal fills is a vital step for die-to-die, die-to-wafer hybrid bonding. The design and method described herein allows for die singulation to maintain a clean surface and clean edge burrs for hybrid bonds.

There may be a fine pitch interface connection (e.g., less than 10 μm), with thin 3DI stacks for example that are 5 μm thick with multi-layers. The bond is through surface monolayer de-hydroxylation of silanol. The goal is to have extremely flat and clean surfaces and edge (e.g. less than 0.1 nm), and no surface and edge debris by dicing.

Wafer singulation may be challenging. Metal fills in the dicing street are needed for low-K dielectric strength, however. Mechanical, UV laser, and RIE dicing potentially leave edge and surface damages and debris. For stealth dicing, the cleanest surface is in a blank wafer. A crack stopper in a device wafer leaves damages and debris by stealth dicing, where the stealth dicing uses an IR laser to crack Si inside the Si bulk.

A solution to these issues is to leave a thin (e.g. 20 μm) dicing street without crack-stopper metal fills, and to perform stealth dicing from the wafer back in the blank streets to form no-damage dicing.

Thus, described herein is a dicing street design for hybrid bonding, leaving a 20 μm wide metal free street. A narrow width is provided so as to not affect an ILD crack. The design is easier for CMP dish control, and wide enough for a dicing laser beam. The design provides for a metal free zone for stealth dicing.

If metal fill is to be used, the fill pattern is non-staggered in both dicing directions. The metal-fill structure within the device seal border needs to be staggered to maintain hermiticity. Outside the seal border, especially within the dicing street, the metal fills need to be non-staggered to facilitate a singulation that is free of edge burrs.

The method of fabrication described herein may use ancillary processes that are used when there is no dicing street. All alignment marks are left towards the die 20 μm within the center line, using a temperature of 40 degrees Celsius to 120 degrees Celsius, as well as a CMP process.

In the examples described herein, a 20 μm metal free street is created. This metal free-zone allows stealth IR laser through. The internal stress will crack (e.g. with dicing) only the dielectric within the 20 μm street. There are no metal fills involved in the dicing streets. Therefore, no metal can smear, melt and affect dicing quality. Using a non-staggered fill design in x, y, z (all three directions), stealth dicing with lower power can maintain a clean dicing edge, and crack only within dielectrics and the silicon (Si) bulk.

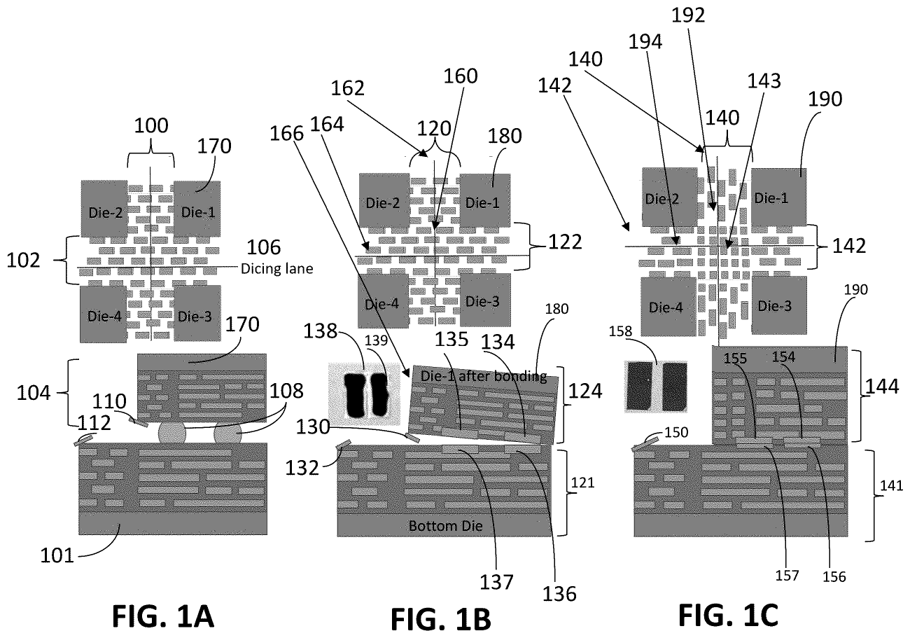

FIG. 1A shows a top panel and a bottom panel, where the top panel of FIG. 1A shows a top view of an intersection of a dicing street x (horizontal) 102 and a dicing street y (vertical) 100, which intersection separates the wafer into Die-1 170, Die-2, Die-3, and Die-4, and where the bottom panel of FIG. 1A shows a separated die (which can be either Die-1 170, Die-2, Die-3, or Die-4, but as shown is Die-1 170) bonded to another bottom die 101 with a solder joint 108.

In particular, FIG. 1A shows a top-down view of vertical die street (100) and horizontal die street (102) together with a cross-sectional view (104) of the die street (100). There is a burr 110 protruding from die street corner 100 and a burr 112 protruding from die 101. Die-1 170 is joined to die 101 using a solder joint 108. The presence of the burrs (110, 112) is a non-issue for the solder join 108. Shown also in FIG. 1A is dicing lane (street) 106. Each dicing burr (110, 112) is less than 5 nm, and each dicing burr (110, 112) does not impact the solder joint 108. The solder joint 108 is approximately 30 μm wide between die 170 and die 101.

A dicing street is an area reserved to be diced, but not diced yet, where the wafer is still one piece. Dicing tracks and dicing streets are used for dicing, where the dicing cuts the wafer into many dies. All dies are bounded by dicing tracks along die edges. Burrs are produced along the tracks, after the wafer is diced into dies.

FIG. 1B shows a top panel and a bottom panel, where the top panel of FIG. 1B shows a top view of a horizontal (in the x direction) dicing street 122 and a vertical (in the y direction) dicing street 120, where the intersection of the horizontal dicing street 122 and the vertical dicing street 120 separates the wafer into Die-1 180, Die-2, Die-3, and Die-4, and where the bottom panel of FIG. 1B shows a separated die (either from Die-1, Die-2, Die-3, or Die-4, but as shown, Die-1 180) hybrid bonded to another bottom die, where the burr impacts a hybrid bond because a dicing street design is not used.

In particular, FIG. 1B shows a top-down view of a wafer at the intersection of dicing streets 120 and 122, which separate the wafer into Die-1 180, Die-2, Die-3, Die-4, with four corners together and with a cross-sectional view (124) along the die dicing street (120) after Die-1, e.g., is hybrid bonded to a bottom wafer substrate 121. Burr 130, produced during dicing along dicing street 120, protrudes from Die-1 along dicing street edge 120 and burr 132 protrudes from bottom die 121 (which is diced out from another wafer, not shown here, but with burr 132 along its dicing edge). The shown burrs (130, 132) are a huge issue for hybrid bonding. Hybrid bonding, where there are (pads) (134, 135) on Die-1 180 (in cross-section 124) joined to Bottom Die (121) at the pads (136, 137), requires a flat surface of generally less than 0.3 nm, for example between Die-1 (cross-section 124) and Die 121. Therefore, because burr 130 is approximately 5 nm or thicker, the burr 130 impacts the hybrid bond. The hybrid bonding burrs (including burr 130) cause a bonding defect, which defect is shown as the white borders in FIG. 1B as item 138 and 139 (edge burr defects) in the accompanying Sono scan images. FIG. 1B further shows dicing track 160 and top die dicing street cut edges (162, 164, 166).

FIG. 1C shows a top panel and a bottom panel, where the top panel of FIG. 1C shows a top view of a horizontal dicing street 142 in the x direction and a vertical dicing street 140 in the y, where the intersection of the horizontal dicing street 142 and the vertical dicing street 140 separates the wafer into Die-1, Die-2, Die-3, and Die-4, and where the bottom panel of FIG. 1C shows a separated die (either from Die-1 190, Die-2, Die-3, or Die-4 and as shown, Die-1 190) hybrid bonding without burr impact with use of a dicing street design.

In particular, FIG. 1C shows a top-down view dicing street 140 (vertical) and dicing street 142 (horizontal), as well as dicing track 192 (vertical) and dicing track 194 (horizontal). Die-1 190, Die-2, Die-3 and Die-4 are located on the four corners of the dicing street intersection (143). Die-1, one of the four dies of the dicing intersection 143 together with a cross-sectional view 144 of the die Die-1 190, shows a hybrid bonding to die 141 (a separate bottom die). For the hybrid bonding to occur, there should be no burrs, as burr less dicing is vital to hybrid bond yield. In FIG. 1C hybrid bonding of die-1 (190) to die 141 (a separate bottom die) is implemented with pads (154, 155) that are joined to die-1 190 and pads (156, 157) that are joined to die 141, such that pad 154 is joined to pad 156 and pad 155 is joined to pad 157. The burr 150 (from dicing track on separate bottom die) that protrudes from die 141 does not impact the hybrid bonding, which hybrid bonding is also shown by item 158 in Sono scan images that has no white borders 138/139.

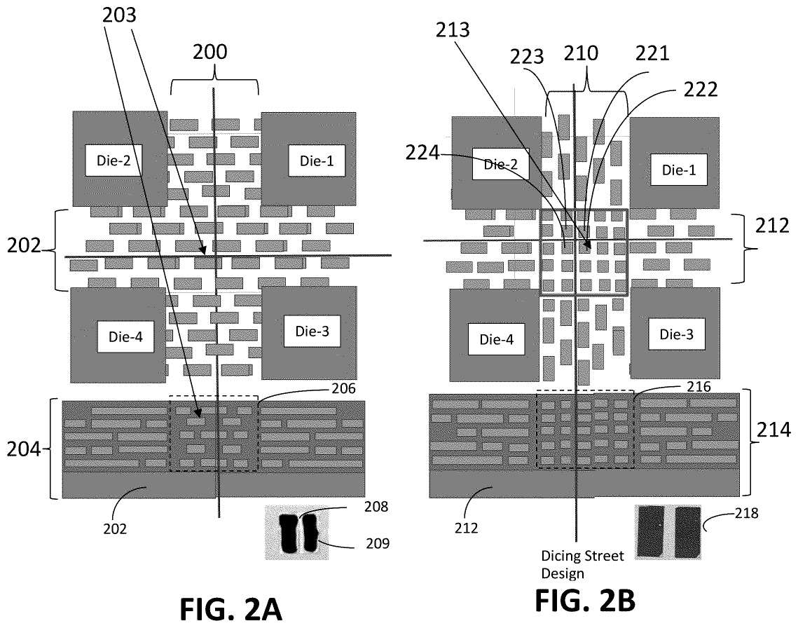

FIG. 2A shows a top-down view of Die-1, Die-2, Die-3, and Die-4 in a dicing intersection between a vertical dicing street 200 and a horizontal dicing street 202, and a cross-sectional view 204 of the horizontal dicing street 202, where a typical dicing street design used, and where in the y-direction, the metal fill is staggered.

In particular, FIG. 2A shows a top-down view of dicing street 202 (horizontal) and dicing street 200 (vertical) at the dicing intersection 203. Together the dicing street 202, the dicing street 200, and the dicing intersection 203 separate the wafers into Die-1, Die-2, Die-3, and Die4, on the four corners of intersection 203. FIG. 2A also shows a cross-sectional view 204 between the Die-1 and the Die-2 along dicing street 202, with implementation of a dicing design 206 (shown is a cross sectional view of dicing intersection 203 in perpendicular to dicing street 200, along street 202). When the dicing design 206 is used, the dicing burr impacts the hybrid bonding yield by producing edge defect 208 and 209 (the white borders flank the dark die center).

FIG. 2B shows a top-down view of Die-1, Die-2, Die-3, and Die-4 in a dicing intersection between a vertical dicing street 210 and a horizontal dicing street 212, and a cross-sectional view 214 of the horizontal dicing street 212, where a dicing street design described herein is used, and where the metal fills in both the x direction and the y direction are not staggered. The metal fills shown in FIG. 2B include metal fills 221, 222, 223, and 224. In the design shown in FIG. 2B, the metal fills are not staggered in the y direction between metal fill 223 and metal fill 221, and between metal fill 222 and metal fill 224. Further, in the design shown in FIG. 2B, the metal fills are not staggered in the x direction between metal fill 221 and metal fill 222, and between metal fills 223 and metal fill 224.

In particular, FIG. 2B shows a top-down view of Die-1, Die-2, Die-3, and Die-4 in the dicing intersection 213 between dicing street 210 (vertical) and dicing street 212 (horizontal), and a cross-sectional view 214 of the horizontal dicing street 212, where a dicing street design 216 as described herein is used. When the dicing street design 216 is used, the hybrid bonding 218 is not impacted by a burr by non-stagger metal layers.

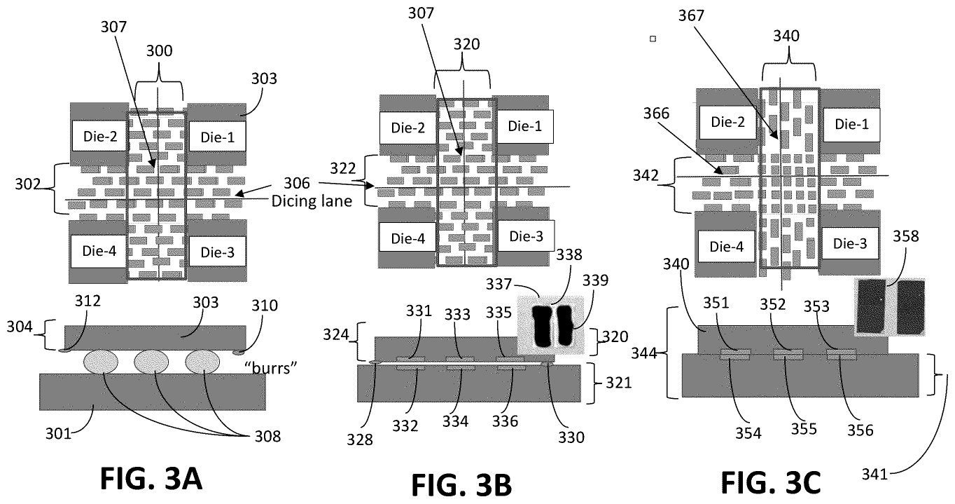

FIG. 3A shows a top-down view of Die-1, Die-2, Die-3, and Die-4, at a dicing intersection of horizontal dicing street (302) and vertical dicing street (300), together with a cross-sectional view (304) of one die 303 of the four dies solder joined to a bottom die 301. Burrs (310, 312) protrude from die 303, which die 303 can be any of the four dies. For example, when die 303 is Die-1, Die-1 is joined to die 301 using a solder joint 308. The presence of the burrs (310, 312) is a non-issue for the solder join 308.

Shown also in FIG. 3A (and FIG. 3B) is horizontal dicing lane (track) 306 and vertical dicing lane (track) 307. Dicing track 306 is less likely to produce dicing debris as it runs in the non-staggered direction (302, 322). Dicing track 307 is more likely to produce dicing debris as it runs in the staggered direction (300, 320), meaning it has to break the metal fills as the fills are staggered and are intended to stop any crack by the staggered metal fills, prone to produce dicing debris. Each dicing burr (310, 312) is less than 5 nm, and each dicing burr (310, 312) does not impact the solder joint 308, because the solder joint 308 is 30 μm high between Die-1 303 and bottom die 301.

FIG. 3B shows a top-down view of Die-1, Die-2, Die-3, and Die-4, at a dicing intersection of a horizontal dicing street 322 and a vertical dicing street 320, together with a cross-sectional view of one die of the four dies hybrid bonded to a bottom die 321 where the edge burr impacts the bonding quality

In particular, FIG. 3B shows a top-down view of horizontal dicing street (322) and vertical dicing street (320) together with a cross-sectional view (324) of the vertical dicing street (320). The intersection of dicing street 320 and dicing street 322 separates the wafer into four dies, Die-1, Die-2, Die-3, and Die-4. The shown burrs (328, 330), which may protrude from either the edges of die-1, die-2, die-3, die-4, are a huge issue for hybrid bonding. Hybrid bonding, where there are bonds or pads (331, 333, 335) joined to Die-1 (or Die-2, Die-3, Die-4) and bonds or pads (332, 334, 336) joined to die 321 (die 321 is a separate bottom die), requires a flat surface of generally less than 0.3 nm in height variation. Because each edge burr (328, 330) is more than 5 nm in surface topography and size, the burrs (328, 330) impact the hybrid bond yield. The hybrid bonding defect is also shown as items 338 and 339, the lighter shaded zigzag borders around the darker shaded center parts. Items 338 and 339 are shown in a typical ultrasound scan 337 of the dies after hybrid bonding with edge defects by the dicing burrs on edges.

FIG. 3C shows a top-down view of horizontal dicing street 342 and vertical dicing street 340, separating the wafer into Die-1, Die-2, Die-3, and Die-4 into four quadrants (each die in a quadrant), together with a cross-sectional view 344 of a die 341 (die 341 is Die-1 or Die-2 or Die-3 or Die-4) hybrid bonded to a bottom die 341. For the hybrid bonding to have a good bonding yield, there should be no burrs, as burr less dicing is vital to hybrid bond yield. In FIG. 3C hybrid bonding of the die 340 to die 341 is implemented with bonds or pads (351, 352, 353) that are joined to die 340 and bonds or pads (354, 355, 356) that are joined die 341, such that bond or pad 351 is joined to bond or pad 354, bond or pad 352 is joined to bond or pad 355, and bond or pad 353 is joined to bond or pad 356. Burrs dicing does not impact the hybrid bonding shown in FIG. 3C, which hybrid bonded dies with good bonding is also shown in ultrasonic scan image item 358, without the defective white borders around darker die center. The burr-less dicing along dicing street 342 and dicing street 340 is achieved by non-staggered metal fills in the metal fill design shown in FIG. 3C. In FIG. 3B, the vertical dicing street 320 is staggered, and is prone to produce edge burrs, as shown in the accompanying ultrasonic scan of hybrid bonded die image 337 with white borders. FIG. 3C further shows horizontal dicing lane (track) 366 and vertical dicing lane (track) 367.

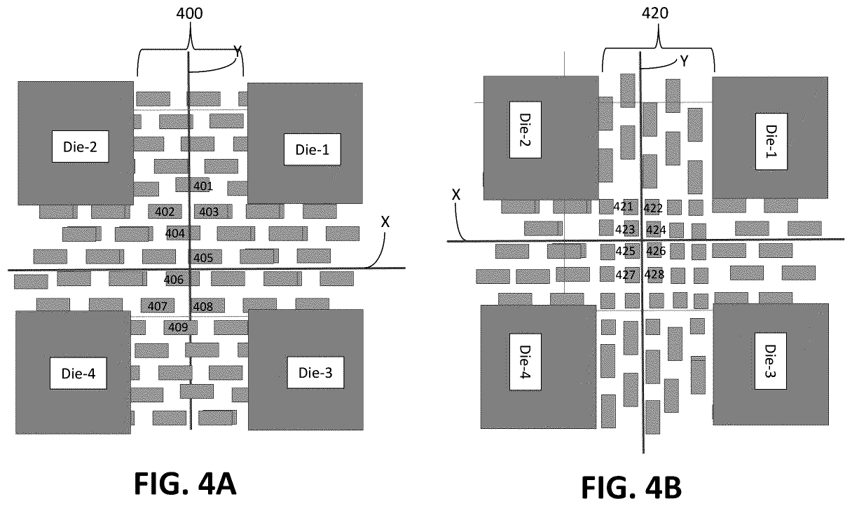

FIG. 4A is a top-down view of a dicing street 400 having a Y-direction (vertical) staggered metal fill pattern, representing for example a fill cutting into the metal fill in the Y-direction. As shown in FIG. 4A, the fill pattern is staggered in the Y direction across fill items (e.g. metal fill items) 401, 402, 403, 404, 405, 406, 407, 408, and 409. The Y-direction staggered fill leads to a fills break (e.g. a metal fills break), and a high potential for edge burrs for hybrid bonding.

FIG. 4B is a top-down view of a dicing street 420 having a non-staggering fill pattern in both X and Y directions, representing for example a cut into the dielectric in both directions. As shown in FIG. 4B, the fill pattern is non-staggered in the X direction across metal items 423, 424, 425, 426, and non-staggered in the Y direction across metal items 421, 422, 423, 424, 425, 426, 427, 428. In FIG. 4B, there are stealth dicing breaks in the dielectric channels, resulting in a cleaner dicing.

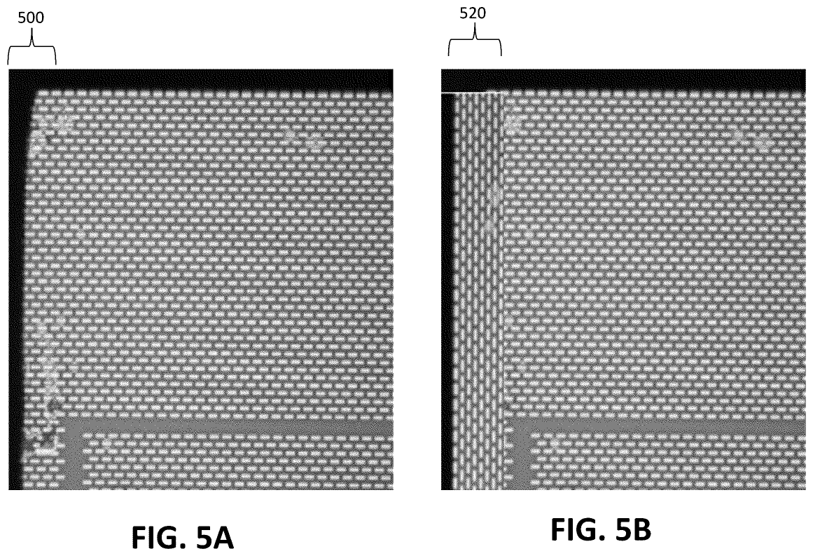

FIG. 5A is a view of a dicing street fill pattern 500 with a staggering fill pattern in one direction (vertical) after the filled is diced, which leads to Y side copper (Cu) snap with jagged edge when the snap crosses the staggered fill pattern. FIG. 5B is a view of a dicing street fill pattern 520 with a non-staggering fill pattern in both the X and Y directions, where both directions are zipperable.

In an embodiment, a method of forming a dicing street device comprises 1) implementing a dicing street design for at least one level (top most level), and repeating the path for all levels minus a 5-10 μm clear path, 2) building wafers to a hybrid bonding surface, 3) protecting the layers, 4) thinning the wafers, 5) flipping the wafer on to a dicing tape frame, and performing stealth dicing of the water along the metal-less street, and 6) snapping and stretching the dicing tape to separate the dies.

In another embodiment, a method includes 1) forming a dicing street design, 2) in each level, removing 5-20 μm wide fills shapes, 3) building a wafer to finish with a hybrid bond surface, 4) protecting the surface with a resist, 5) thinning the wafer, 6) using stealth dicing to align from the wafer back side into the metal-less street, and 7) snapping and stretching the dicing tape to separate the dies.

The methods and structures described herein represent an important option of hybrid bonding wafer singulation to keep the surface and corners debris-free.

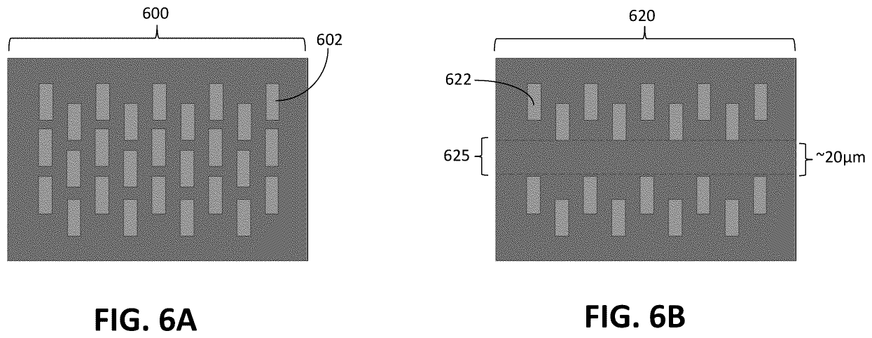

FIG. 6A shows a top view of a dicing street design 600 without a straight path through the metal fills 602 in the horizontal direction. In the vertical direction, however, there are several straight paths through the metal fills. FIG. 6B shows a view of a dicing street design 620 with a 20 um straight path 625 (without metal fill) in the horizontal direction. There is no metal (e.g. metal 622) within the dicing street 625, and the dicing street 625 is approximately 20 μm wide.

The metal free zone as described herein may have a width that is greater than or equal to 3 μm and less than or equal to 75 μm, with an optimum or preferable width of around 20 μm (e.g. substantially equal to 20 μm).

Described herein is a structure comprising: a metal free zone within at least one level of the structure; and a fill pattern that is not staggered along a first direction and that is not staggered along a second direction. The structure may include a staggered interlayer dielectric within at least one level of the structure, preferably the top layer, which impacts hybrid bonding directly. Other layers could also impact hybrid bonding but may to a lesser degree because the burrs would locate lower in topography and would be less likely to impact hybrid bonding as directly as the top layer.

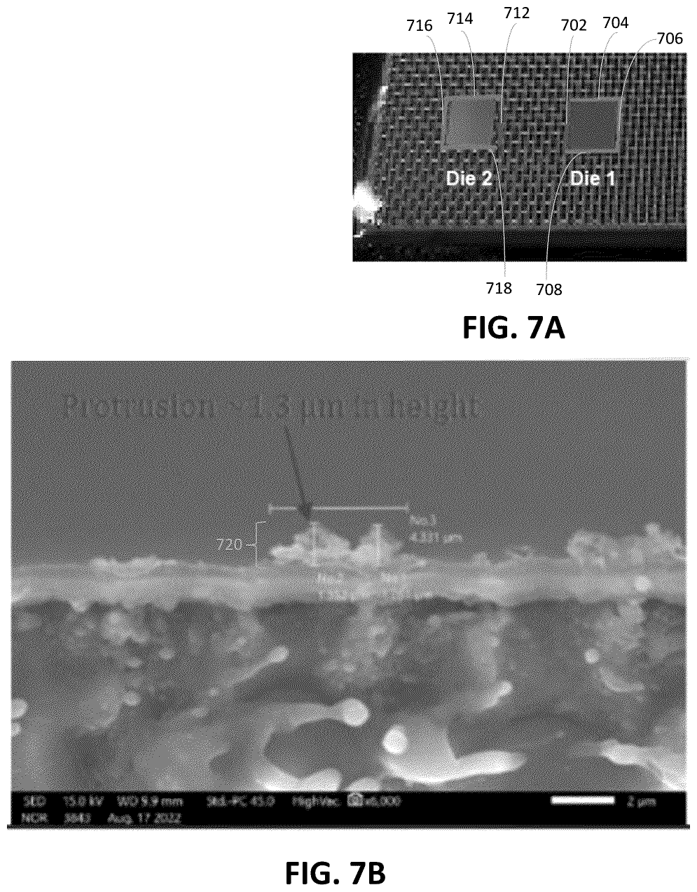

FIG. 7A shows sides of dies separated at picking. The fabrication procedure includes checking for protrusions (e.g. burrs) greater than 0.5 μm on die edges as shown in FIG. 7A. This involves comparing the side that was separated at picking (702 of Die 1, 712 of Die 2) with the other sides that were separated normally (704, 706, 708 of Die 1, and 714, 716, 718 of Die 2). After singulation, pick a piece, and inspect under scanning electron microscopy (SEM) to see if the edges have protrusions due to metal wiring. For silicon (Si), chipping is expected. However, for metal wiring, the protrusions may hang there and cause a bonding issue. Thus the process includes looking for metal burrs.

FIG. 7B is an edge on scanning electron microscopy (SEM) that shows a burr of size 1.3 μm due to laser cutting, and debris from the UV laser. The same is done for a stealth cut die (i.e. look for burrs). The resist protection coating might make a clutter for SEM. Acetone can be used to remove the protection coating before SEM, if the burrs pose an issue for SEM. In FIG. 7B, the SEM was performed at 15 kV. Scanning electron microscopy secondary electron imaging (SEM-SEI) may be sensitive to surface texture. In FIG. 7B, a thin palladium (Pd) coating was sputtered on the sample before analysis.

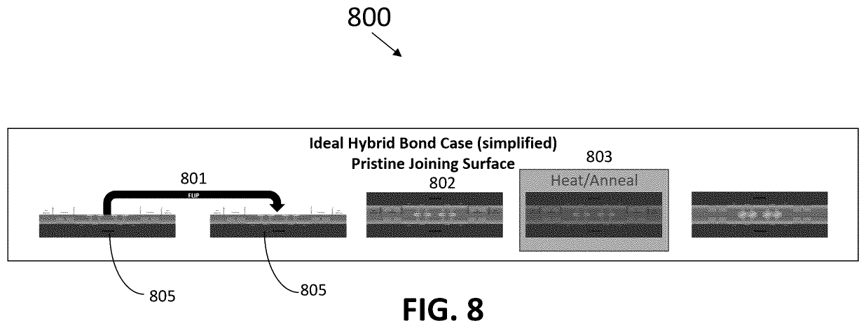

FIG. 8 shows an example hybrid bonding process flow 800. The process including flipping (801) the wafer 805, bonding 802, and heating and annealing 803.

Accordingly, described herein is a dicing street structure of a size of approximately 20 μm wide without metal fills within the street. This allows for metal to not affect the dicing or stealth dicing quality. Similar to blanks wafers, the herein described dicing street results in a dicing edge clear of burr and that is usable for hybrid bonding. The examples described herein provide a method for keeping the street clean and free of nanometer sized debris during dicing.

The herein described method includes leaving a dicing street free of metal that is wide enough for laser stealth dicing but narrow enough than would not affect low-K materials, to create a metal free zone to separate the dies without producing debris on the hybrid bonding surface. For hybrid bonding, the surface is kept clean from nanometer sized debris during dicing by a protection layer.

The problem addressed by the examples described herein is that during dicing, the edge may create additional smear and melting by the dicing wheel or the laser, that are stuck to the edges, if metal fills are present in the dicing street. The examples described herein are directed to methods for a clean die separate without produce debris, using stealth dicing. This is accomplished by creating a 20 um wide metal free street, and/or using un-staggered metal fills with a lower power IR stealth laser, which produces a dicing cut that is free of debris.

The examples described herein resolve metal contamination. Metal fills are designed in a non-stagger pattern in both dicing directions. A lower power IR laser is used for dicing the wafer internally, without producing debris and without melting the metal. The non-stagger design allow the cracks formed by an infrared (IR) internal crack to be split along the dielectric but not in metal, therefore producing a clean split. Therefore, the herein described examples address the shortcoming of using a laser scribe to clean off the top layers of material and using plasma dicing, and yield a debris free result for hybrid bonding dicing.

The structure described herein facilitating the crack only in dielectric for a clean crack. Thus, an approach is to stop the crack by forming a staggered metal fill.

If the front surface of the dicing street has metal fills, separation may still disturb the metal structure and cause surface damage. This is particularly the case if backside scoring is used because the dicing blade width can cause dicing overhang and form debris. Even stealth dicing (internal scoring) cannot control such debris generation if the metal fills are not designed to facilitate cracks within dielectrics only, and not in metal fills. A technical effect of the examples described herein is to address such issue. In the examples described herein, non-staggered metal fills are used, with sufficient strong support in x, y, z direction to protect the low-K material during the process while allowing the crack to propagate along the dicing street once the cracks are initiated by the stealth internal scoring. The examples described herein use a fill design to allow crack propagation without disturbing the metal fills, which is important for a debris free dicing.

Further, the examples described herein use a stealth IR laser to do internal scoring and therefore no scoring debris is produced. During shaping (stretching) the non-stagger metal fills allow cracks to propagate along a nonmetal ILD area, where no metal is disturbed, to create clean dicing channels. Different from using CMP to remove debris, the examples described herein use a metal fill design to stop debris from forming.

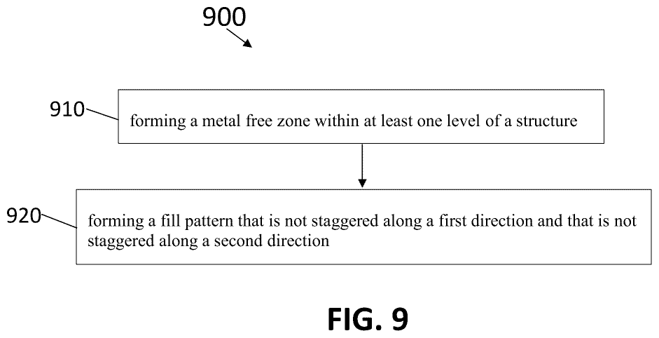

FIG. 9 is a logic flow diagram to implement a method 900, based on the examples described herein. At 910, the method includes forming a metal free zone within at least one level of a structure. At 920, the method includes forming a fill pattern that is not staggered along a first direction and that is not staggered along a second direction.

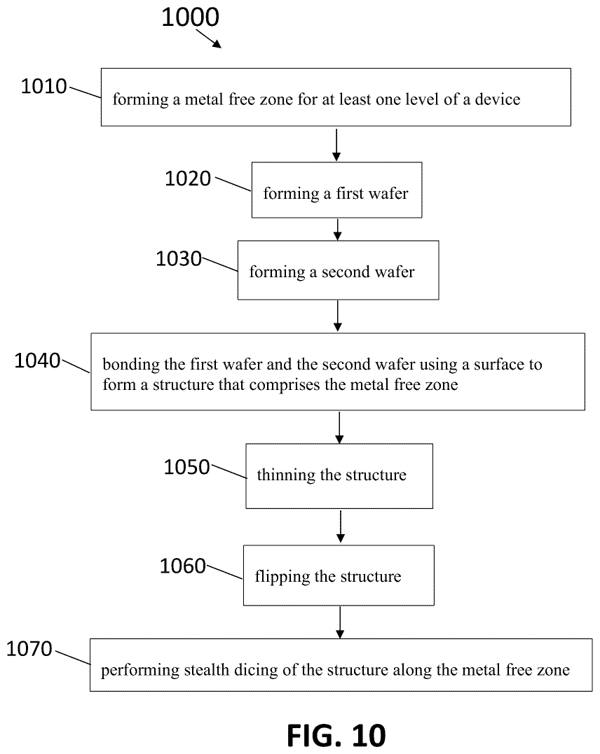

FIG. 10 is a logic flow diagram to implement a method 1000, based on the examples described herein. At 1010, the method includes forming a metal free zone for at least one level of a device. At 1020, the method includes forming a first wafer. At 1030, the method includes forming a second wafer. At 1040, the method includes bonding the first wafer and the second wafer using a surface to form a structure that comprises the metal free zone. At 1050, the method includes thinning the structure. At 1060, the method includes flipping the structure. At 1070, the method includes performing stealth dicing of the structure along the metal free zone.

Another embodiment of the examples described herein relates to a method for burr-free dicing streets for hybrid bonding.

Wafers with metal in the dicing street are particularly difficult to dice for hybrid bonding applications. Saw dicing through the metal street results in a metal fill to warp and damage the die edge or surface. Laser dicing ablates metal and forms recast (approximately 1.5 um high) on the die edge surface making surface contact difficult. Plasma dicing also needs exposed Si for etching. Stealth dicing is done from the back and poses a low risk to the bonding surface, but needs tape stretching for separation, which is not possible with a metal fill. Keeping a gap in the metal fill is not always possible due to CMP concerns.

Therefore, described herein is a solution this problem, involving filling the area around the metal with ultra-low k dielectric material which, when exposed to a stealth UV laser, embrittles and acts as separation initiation point for the wafer during tape expansion post stealth dicing.

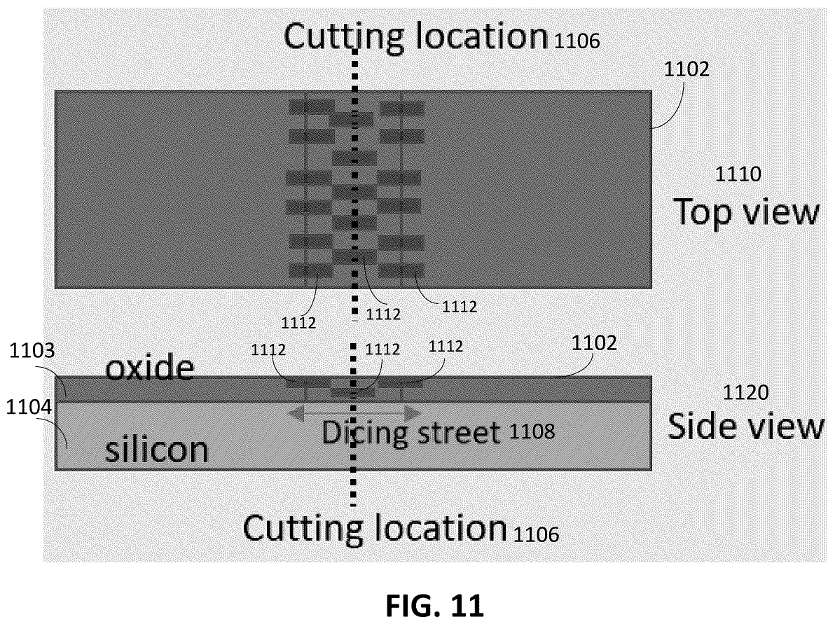

FIG. 11 shows a top view 1110 of a die 1102 and a side view 1120 of the die 1102, and a cutting location 1106 and dicing street 1108 of the die 1102. The die 1102 has an oxide layer 1103 and a silicon layer 1104. Metal 1112 is shown within the die (a subset of the metal items are shown as items 1112).

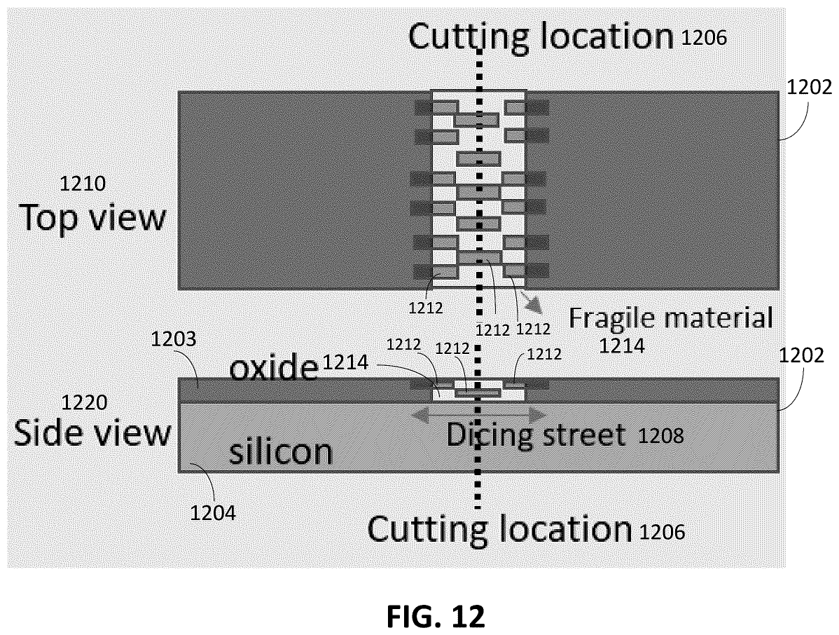

FIG. 12 shows a top view 1210 of a die 1202 and a side view 1220 of the die 1202, and a cutting location 1206 and a dicing street 1208 of the die 1202. An area around the metal (some of the metal items are shown as items 1212) is filled with a fragile material 1214. The die 1202 has an oxide layer 1203 and a silicon layer 1204.

Thus, described herein is a structure 1202 having a metal fill 1212 that is surrounded by fragile material 1214, for example an ultra-low k dielectric material.

Further described herein is a method to remove burr on a dicing street device, comprising: (1) depositing ultra-low k or fragile material in the dicing streets, (2) with or without adding metal fill with or without a gap of 10-20 μm aligned with the center of the dicing street; metal fill could be present in the ultra-low k layers, (3) exposing the low-k material to a UV laser to form airgaps which serve as a crack initiation region, and (4) possibly adding metal passivation at the edge of the dicing street to prevent crack propagation.

Further described herein is a method comprising: (1) while forming a dicing street, adding ultra low-k (fragile) material in each level in the dicing path, (2) processing a front side of the wafer for hybrid bonding, and (3) expose the low-k material to a stealth UV laser to create air gaps on the dicing street. Exposing the low-k material to a stealth UV laser to crate air gaps on the dicing street may be implemented by a means of stealth dicing from the back for the entire stack. Alternatively, exposing the low-k material to a stealth UV laser to crate air gaps on the dicing street may be implemented by focused UV exposure from the top-side. The method further includes (4) pulling the dicing tape to separate the wafers, where air gaps act as a crack initiation region.

The examples described herein are useful for strategic chiplet packaging or hybrid bonding applications which require burr-free dicing streets.

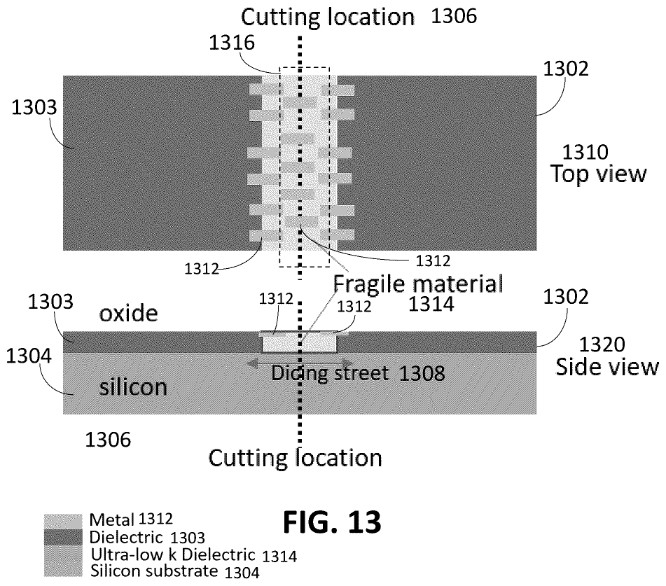

FIG. 13 shows an embodiment of the examples described herein. FIG. 13 shows a top view 1310 of a die 1302 and a side view 1320 of the die 1302, and a cutting location 1306 and a dicing street 1308 of the die 1302. An area around the metal (some of the metal items are shown as items 1312) is filled with a fragile material 1314. The fragile material 1314 is for example an ultra-low k dielectric material. The die 1302 has an oxide layer 1303 (or dielectric layer 1303) and a silicon layer 1304. In the embodiment shown in FIG. 13, the cutting location 1306 goes through or traverses some of the metal 1312, depicted as region 1316.

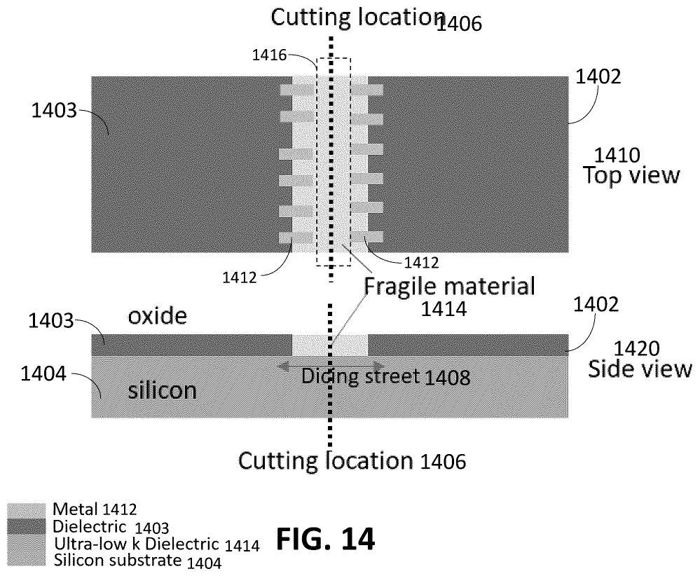

FIG. 14 shows an embodiment of the examples described herein. FIG. 14 shows a top view 1410 of a die 1402 and a side view 1420 of the die 1402, and a cutting location 1406 and a dicing street 1408 of the die 1402. An area around the metal (some of the metal items are shown as items 1412) is filled with a fragile material 1414. The fragile material 1414 may be an ultra-low k dielectric material. The die 1402 has an oxide layer 1403 (or dielectric layer 1403) and a silicon layer 1404. In the embodiment shown in FIG. 14, the cutting location 1406 does not go through or traverse some of the metal 1412, depicted as region 1416.

A SiCOH (ULK material) method is used to create air pockets in the dicing street 1408 to ease splitting new masks. There is no metal in the dicing street 1408, thus assuming stealth dicing, there is a gap in the metal fill.

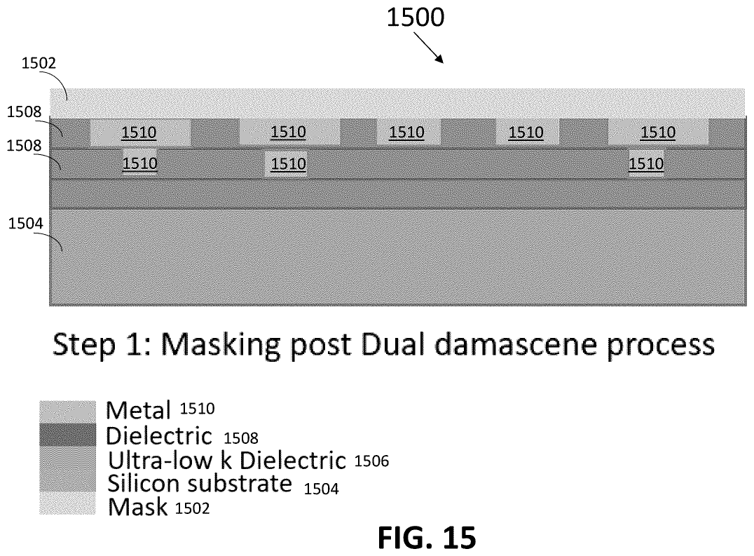

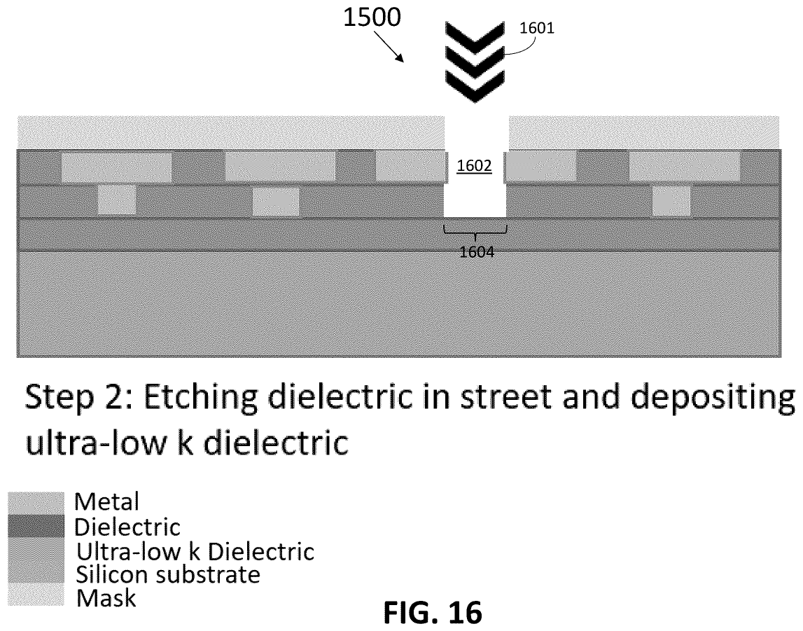

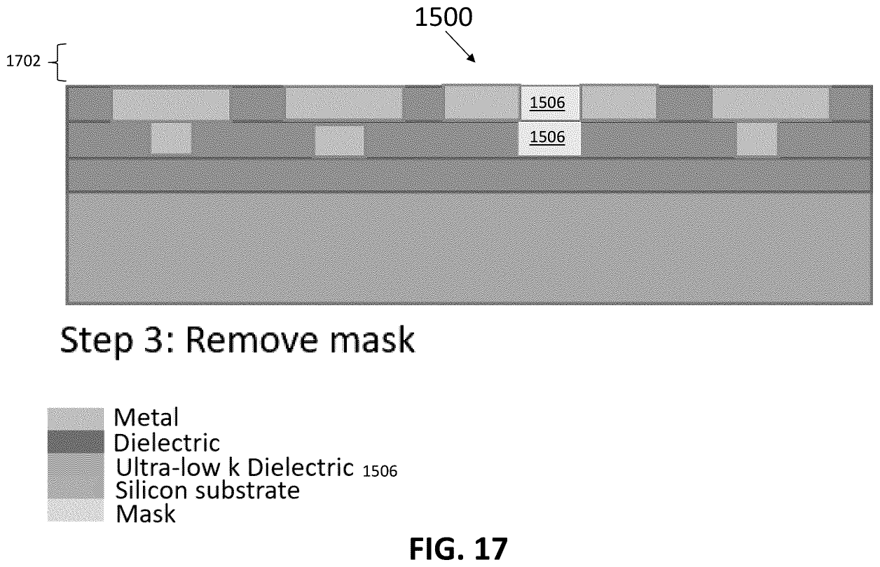

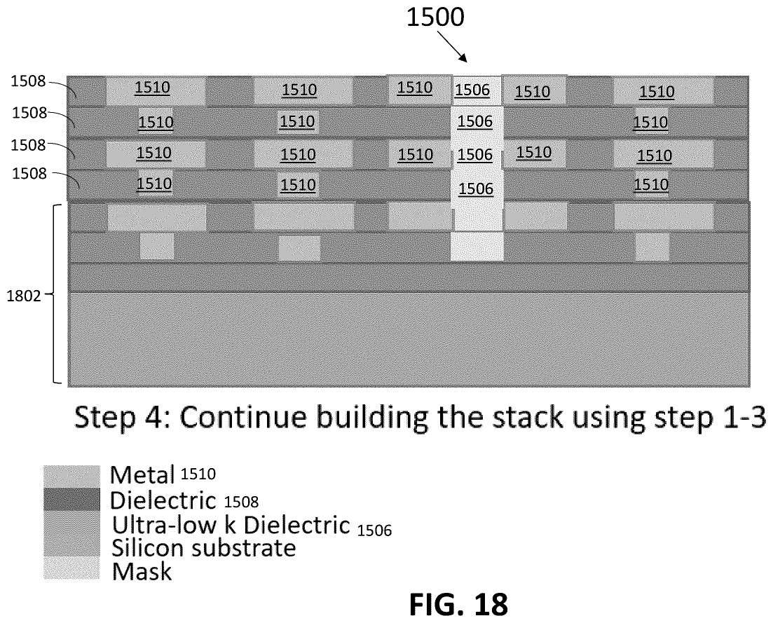

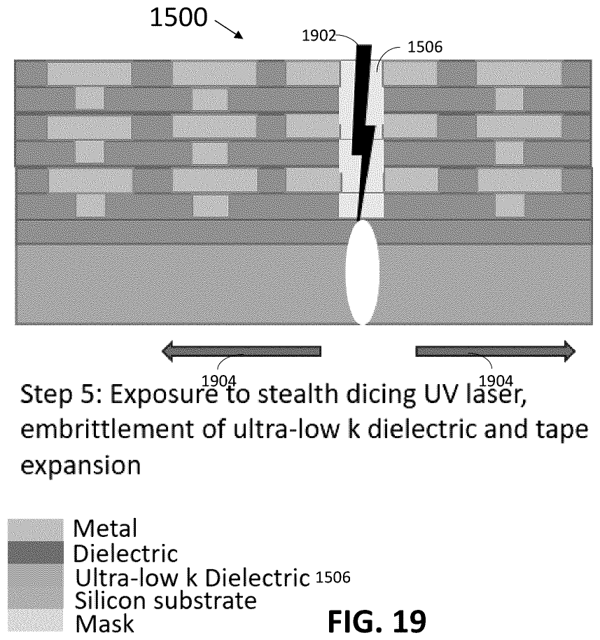

FIG. 15, FIG. 16, FIG. 17, FIG. 18, and FIG. 19 show a process flow, based on the examples described herein. The process includes damascene followed by masking and etching the dicing lane, and deposition of low-k materials only in the dicing lane. A benefit and technical effect of the process flow is that exposure to the UV laser may cause gasification of ultra low-k materials. The excess pressure built-up in the intermediate BEOL layers could assist in wafer separation.

FIG. 15 shows a first operation of the process flow 1500, that includes masking post a dual damascene process. The damascene process includes forming metal 1510 in a pattern within dielectric layers 1508 applied above a silicon substrate 1504. A mask 1502 is applied above and in contact with the metal 1510 and one of the dielectric layers 1508.

FIG. 16 shows a second operation of the process flow 1500, including etching dielectric (forming 1601 etch 1602) in the street 1604 and, with reference to FIG. 17, depositing ultra-low k dielectric material 1506. The etch 1602 is formed 1601 within the mask 1502 and the dielectric layers 1508. FIG. 17 shows a third operation of the process flow 1500, including removing the mask 1502 (refer to removed portion 1702).

FIG. 18 shows a fourth operation of the process flow 1500, including continuing building of the stack using operation 1 depicted in FIG. 15, operation 2 depicted in FIG. 16, and operation 3 depicted in FIG. 17. Additional metal 1510 is formed in a pattern within additionally formed dielectric layers 1508 above the already existing structure 1802. Also, ultra-low k dielectric 1506 is formed within the additionally formed dielectric layers 1508. FIG. 19 shows a fifth operation of the process flow 1500, including exposure to a stealth dicing UV laser, embrittlement 1902 of the ultra-low k dielectric 1506 and tape expansion 1904.

Accordingly, described herein is a dicing street filled with ultra-low k and fragile material, which can be used to create air gaps. All metal filling is removed by creating a keep-out or exclusion zone in a small region (such as region 1316 and region 1416) in the dicing street (1208, 1308, 1408, 1604). This ensures that cracks generated by stealth dicing (1092) pass along this zone.

All the levels in the dicing street have the ultra-low k dielectric, not just the fat metal levels. The ultra-low k material is different from low-k dielectric like TEOS as it is porous and has even lower capacitance. Stress at the boundary is not a huge concern. There are already multiple materials in the BEOL levels that have different mechanical properties, which can go through process thermal cycles without a failure. Formation of crack initiation sites on exposure of ultra-low k dielectric to UV (stealth dicing) leads to complete wafer separation (including at fat metal fill levels which are otherwise difficult to cleave using stealth dicing). Ideally, the exposure of the ultra-low k dielectric to UV should be done in a stepwise manner to allow for outgassing. Pressure buildup could result when outgassing is not allowed, but it is not the driving process for wafer separation. Equivalent wafer temperatures would be similar to those observed during usual stealth dicing.

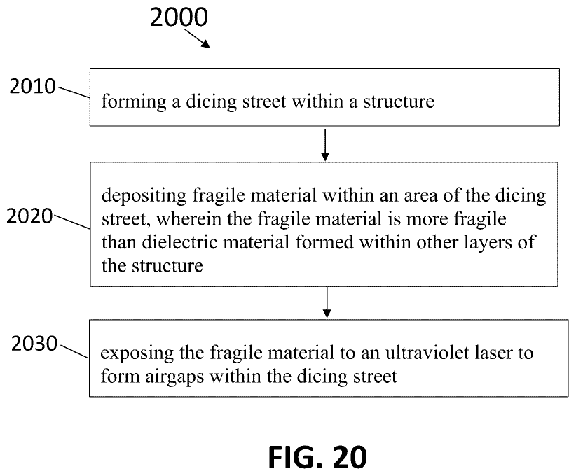

FIG. 20 is a logic flow diagram to implement a method 2000, based on the examples described herein. At 2010, the method includes forming a dicing street within a structure. At 2020, the method includes depositing fragile material within an area of the dicing street, wherein the fragile material is more fragile than dielectric material formed within other layers of the structure. At 2030, the method includes exposing the fragile material to an ultraviolet laser to form airgaps within the dicing street.

Referring now to all the Figures, the following examples are described and disclosed herein.

Example 1. A structure including: a metal free zone within at least one level of the structure; and a fill pattern that is not staggered along a first direction and that is not staggered along a second direction.

Example 2. The structure of example 1, further comprising a plurality of metal free zones within a respective plurality of levels of the structure.

Example 3. The structure of example 1, wherein the fill pattern is not staggered along a dielectric along the first direction and the second direction.

Example 4. The structure of example 1, wherein: the metal free zone has a width that is greater than or equal to 3 μm and less than or equal to 75 μm, or the metal free zone has a width that is substantially equal to 20 μm.

Example 5. The structure of example 1, wherein the metal free zone has a width that is at least 20 μm.

Example 6. The structure of example 1, further comprising a staggered interlayer dielectric within a top layer the structure.

Example 7. The structure of example 1, further including at least one alignment mark within 20 μm of a center line of the structure.

Example 8. The structure of example 1, wherein the first direction is horizontal or vertical, and the second direction is horizontal or vertical, and wherein the structure comprises semiconducting material.

Example 9. A method including: forming a metal free zone within at least one level of a structure; and forming a fill pattern that is not staggered along a first direction and that is not staggered along a second direction.

Example 10. The method of example 9, further including: forming a plurality of metal free zones within a respective plurality of levels of the structure.

Example 11. The method of example 9, further including: forming the fill pattern to be not staggered along a dielectric along the first direction and the second direction.

Example 12. The method of example 9, further including: forming the metal free zone to have width that is greater than or equal to 3 μm and less than or equal to 75 um, or substantially equal to 20 μm.

Example 13. The method of example 9, further including: forming the metal free zone to have a width that is at least 20 μm.

Example 14. The method of example 9, further including: forming a staggered interlayer dielectric within at least one level of the structure.

Example 15. The method of example 9, further including: forming at least one alignment mark within 20 μm of a center line of the structure.

Example 16. The method of example 9, wherein the first direction is horizontal or vertical, and the second direction is horizontal or vertical, and wherein the structure comprises semiconducting material.

Example 17. The method of example 9, further including: dicing along the fill pattern along at least one direction of the structure.

Example 18. The method of example 9, further including: bonding the structure to at least one other structure, and heating and annealing the bonding.

Example 19. A method including: forming a metal free zone for at least one level of a device; forming a first wafer; forming a second wafer; bonding the first wafer and the second wafer using a surface to form a structure that comprises the metal free zone; thinning the structure; flipping the structure; and performing stealth dicing of the structure along the metal free zone.

Example 20. The method of example 19, further including: forming a metal free zone for at least one other level; protecting the first wafer and the second wafer with a resist; and separating the first wafer from the second wafer.

Example 21. A method comprising: forming a dicing street within a structure; depositing fragile material within an area of the dicing street, wherein the fragile material is more fragile than dielectric material formed within other layers of the structure; and exposing the fragile material to an ultraviolet laser to form airgaps within the dicing street.

Example 22. The method of example 21, wherein the fragile material comprises an ultra-low k dielectric material.

Example 23. The method of example 21, further comprising: applying dicing tape to the structure; wherein forming the dicing street within the structure creates two portions of the structure; and pulling the dicing tape to separate the two portions of the structure; wherein the area in which the fragile material is deposited comprises a separation point for the separation of the two portions of the structure.

Example 24. The method of example 21, further comprising: forming a metal fill pattern within the fragile material.

Example 25. The method of example 21, wherein the dicing street is between 10 μm and 20 μm wide, and a cutting location of the dicing street is substantially at a center of the dicing street.

References to a ‘computer’, ‘processor’, etc. should be understood to encompass not only computers having different architectures such as single/multi-processor architectures and sequential or parallel architectures but also specialized circuits such as field-programmable gate arrays (FPGAs), application specific circuits (ASICs), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

One or more memories as described herein may be implemented using any suitable data storage technology, such as semiconductor based memory devices, flash memory, magnetic memory devices and systems, optical memory devices and systems, non-transitory memory, transitory memory, fixed memory and removable memory. The one or more memories may comprise a database for storing data.

As used herein, circuitry may refer to the following: (a) hardware circuit implementations, such as implementations in analog and/or digital circuitry, and (b) combinations of circuits and software (and/or firmware), such as (as applicable): (i) a combination of one or more processors or (ii) portions of processor(s)/software including digital signal processor(s), software, and one or more memories that work together to cause an apparatus to perform various functions, and (c) circuits, such as a microprocessor(s) or a portion of a microprocessor(s), that require software or firmware for operation, even if the software or firmware is not physically present. As a further example, as used herein, circuitry would also cover an implementation of merely a processor (or multiple processors) or a portion of a processor and its (or their) accompanying software and/or firmware. Circuitry would also cover, for example and if applicable to the particular element, a baseband integrated circuit or applications processor integrated circuit for a mobile phone or a similar integrated circuit in a server, a cellular network device, or another network device.

List of abbreviations, which abbreviations may be appended with each other or other characters using e.g. a dash or hyphen (“-”):
3DI three-dimensional integration
ASIC application-specific integrated circuit
BEOL back end of line
CMP chemical mechanical planarization or polishing
D2D die-to-die
D2 W die-to-wafer
FPGA field-programmable gate array
ILD interlayer dielectric
IO input output
I/O input output
IR infrared
K relative dielectric constant (e.g. low-K)
RIE reactive-ion etching
SEI secondary electron imaging
SEM scanning electron microscopy
Si silicon
SiCOH carbon doped oxide dielectric comprised of silicon (Si), carbon (C), oxygen (O), and hydrogen (H)
TEOS tetraethyl orthosilicate
ULK ultra-low k
UV ultraviolet

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A structure comprising:
a metal free zone within at least one level of the structure; and
a fill pattern that is not staggered along a first direction and that is not staggered along a second direction.

2. The structure of claim 1, further comprising a plurality of metal free zones within a respective plurality of levels of the structure.

3. The structure of claim 1, wherein the fill pattern is not staggered along a dielectric along the first direction and the second direction.

4. The structure of claim 1, wherein:
the metal free zone has a width that is greater than or equal to 3 μm and less than or equal to 75 um, or
the metal free zone has a width that is substantially equal to 20 μm.

5. The structure of claim 1, wherein the metal free zone has a width that is at least 20 μm.

6. The structure of claim 1, further comprising a staggered interlayer dielectric within a top layer the structure.

7. The structure of claim 1, further comprising at least one alignment mark within 20 μm of a center line of the structure.

8. The structure of claim 1, wherein the first direction is horizontal or vertical, and the second direction is horizontal or vertical, and wherein the structure comprises semiconducting material.

9. A method comprising:
forming a metal free zone within at least one level of a structure; and
forming a fill pattern that is not staggered along a first direction and that is not staggered along a second direction.

10. The method of claim 9, further comprising:
forming a plurality of metal free zones within a respective plurality of levels of the structure.

11. The method of claim 9, further comprising:
forming the fill pattern to be not staggered along a dielectric along the first direction and the second direction.

12. The method of claim 9, further comprising:
forming the metal free zone to have width that is greater than or equal to 3 μm and less than or equal to 75 um, or substantially equal to 20 μm.

13. The method of claim 9, further comprising:
forming the metal free zone to have a width that is at least 20 μm.

14. The method of claim 9, further comprising:
forming a staggered interlayer dielectric within at least one level of the structure.

15. The method of claim 9, further comprising:
forming at least one alignment mark within 20 μm of a center line of the structure.

16. The method of claim 9, wherein the first direction is horizontal or vertical, and the second direction is horizontal or vertical, and wherein the structure comprises semiconducting material.

17. The method of claim 9, further comprising:
dicing along the fill pattern along at least one direction of the structure.

18. The method of claim 9, further comprising:
bonding the structure to at least one other structure, and heating and annealing the bonding.

19. A method comprising:
forming a metal free zone for at least one level of a device;
forming a first wafer;
forming a second wafer;
bonding the first wafer and the second wafer using a surface to form a structure that comprises the metal free zone;
thinning the structure;
flipping the structure; and
performing stealth dicing of the structure along the metal free zone.

20. The method of claim 19, further comprising:
forming a metal free zone for at least one other level;
protecting the first wafer and the second wafer with a resist; and
separating the first wafer from the second wafer.

21. A method comprising:
forming a dicing street within a structure;
depositing fragile material within an area of the dicing street, wherein the fragile material is more fragile than dielectric material formed within other layers of the structure; and
exposing the fragile material to an ultraviolet laser to form airgaps within the dicing street.

22. The method of claim 21, wherein the fragile material comprises an ultra-low k dielectric material.

23. The method of claim 21, further comprising:
applying dicing tape to the structure;
wherein forming the dicing street within the structure creates two portions of the structure; and
pulling the dicing tape to separate the two portions of the structure;
wherein the area in which the fragile material is deposited comprises a separation point for the separation of the two portions of the structure.

24. The method of claim 21, further comprising:
forming a metal fill pattern within the fragile material.

25. The method of claim 21, wherein the dicing street is between 10 μm and 20 μm wide, and a cutting location of the dicing street is substantially at a center of the dicing street.
